(19) United States
(12) Patent Application Publication
(10) Pub. No.: US 2026/0150750 A1
(43) Pub. Date: May 28, 2026

(54) ELECTRONIC PACKAGE STRUCTURE AND MANUFACTURING METHOD THEREOF

(71) Applicant: Acer Incorporated, New Taipei City (TW)

(72) Inventors: Kuang-Hua Lin, New Taipei City (TW); Chun-Chieh Wang, New Taipei City (TW); Yu-Ming Lin, New Taipei City (TW); Tsung-Ting Chen, New Taipei City (TW); Kuan-Lin Chen, New Taipei City (TW); Wei-Chin Chen, New Taipei City (TW); Mao-Neng Liao, New Taipei City (TW); Cheng-Wen Hsieh, New Taipei City (TW)

(73) Assignee: Acer Incorporated, New Taipei City (TW)

(21) Appl. No.: 19/392,159

(22) Filed: Nov. 18, 2025

(30) Foreign Application Priority Data
Nov. 27, 2024 (TW) 113145723

(51) Int. Cl. H01L 23/24; H01L 21/56; H01L 23/00; H01L 23/367; H01L 25/16

(52) U.S. Cl. CPC H10W 76/47; H10W 40/22; H10W 74/01; H10W 90/00; H10W 72/07332; H10W 90/734

(57) ABSTRACT

An electronic package structure including a substrate, a first electronic element, at least one second electronic element, a liquid metal disposed on the first electronic element, a heat dissipating member disposed on the first electronic element and presses against the liquid metal, a carrier being translucent and electrically insulating, and an electrically insulating glue coated on the carrier is provided. The first and the second electronic elements adjacent to each other are respectively disposed on the substrate. The carrier and the electrically insulating glue thereon are pasted on the substrate to cover and package the second electronic element. A portion of the liquid metal overflew out of the first electronic element is isolated from the second electronic element via the carrier and the electrically insulating glue. A manufacturing method of electronic package structure is also provided.

### CROSS-REFERENCE TO RELATED APPLICATION

This application claims the priority benefit of Taiwan application serial no. 113145723, filed on Nov. 27, 2024. The entirety of the above-mentioned patent application is hereby incorporated by reference herein and made a part of this specification.

### BACKGROUND

### Technical Field

The disclosure relates to an electronic package structure and a manufacturing method thereof.

### Description of Related Art

When a processor or electronic element in an electronic device operates at a high speed, a large amount of heat energy is often generated, causing the temperature of the processor or electronic element to increase. Excessive temperature will increase the wear on the processor or electronic element, and may even shorten the lifespan of the processor or electronic element. Therefore, heat dissipation is extremely important for the processor or electronic element in the electronic device.

The most common existing heat dissipation methods are the use of thermal paste and heat dissipating member, so that the thermal paste conducts heat from the processor or electronic element to the heat dissipating member. Heat conduction and dissipation are improved through the thermally conductive heat dissipating member. However, the thermal conductivity coefficient of traditional viscous thermal paste is low, which impedes the effective transfer of heat from the processor or electronic element to the heat dissipating members. Therefore, liquid metal thermal paste with high thermal conductivity coefficient gradually replaces traditional paste-type thermal paste and is used in heat dissipation modules of electronic devices.

Although liquid metal thermal paste has a high thermal conductivity coefficient, the cohesion of the liquid metal thermal paste is greater than its adhesion to the surface of the processor or electronic element, rendering it challenging to apply the liquid metal thermal paste uniformly on the surface of the processor or electronic element. In addition, if the amount of liquid metal thermal paste is not carefully controlled, the liquid metal thermal paste may overflow the surface of the processor or electronic element, causing short circuits in the surrounding circuits.

### SUMMARY

An electronic package structure and a manufacturing method thereof are provided in the disclosure to provide a stable heat dissipation mechanism to protect the electronic elements and circuits.

An electronic package structure of the disclosure includes a substrate, a first electronic element, at least one second electronic element, a liquid metal, a heat dissipating member, a carrier, and an electrically insulating glue. The first electronic element and the second electronic element adjacent to each other are respectively disposed on the substrate. The liquid metal is disposed on the first electronic element. The heat dissipating member is disposed on the first electronic element and presses against the liquid metal. Heat generated by the first electronic element is transferred to the heat dissipating member through the liquid metal. The carrier is translucent and electrically insulating. The electrically insulating glue is coated on the carrier and pasted on the substrate along with the carrier, so that the electrically insulating glue covers and packages the second electronic element. At least a portion of the pressed liquid metal overflows the first electronic element and is isolated from the second electronic element via the electrically insulating glue and the carrier.

Based on the above, the electronic package structure and the manufacturing method thereof provide a stable heat dissipation mechanism for electronic elements and circuits through convenient and effective protection measures, in which after the electrically insulating glue is applied to the carrier, the carrier and the electrically insulating glue are pasted to the substrate to cover and package the second electronic element. Next, the electrically insulating glue is cured. Finally, the liquid metal is disposed on the first electronic element, and the heat dissipating member is pressed on the first electronic element, so that the heat generated by the first electronic element is transferred to the heat dissipating member through the liquid metal. Since the aforementioned carrier and electrically insulating glue package the second electronic element and isolate it from surrounding elements, when the heat dissipating member is disposed on the first electronic element and presses against the liquid metal, the liquid metal overflowing from the first electronic element may be isolated via the carrier and the electrically insulating glue, effectively preventing the liquid metal from contacting the second electronic element and causing short circuit.

### BRIEF DESCRIPTION OF THE DRAWINGS

FIG. 1 is a top schematic diagram of an electronic package structure according to an embodiment of the disclosure.

FIG. 2 is a partial cross-sectional diagram of the electronic package structure of FIG. 1.

FIG. 3 is a flowchart of a manufacturing method of an electronic package structure.

FIG. 4A to FIG. 4F are simple schematic diagrams of the manufacturing method of FIG. 3.

FIG. 5A and FIG. 5B respectively are schematic diagrams of electronic package structures of different embodiments of the disclosure.

### DETAILED DESCRIPTION OF DISCLOSED EMBODIMENTS

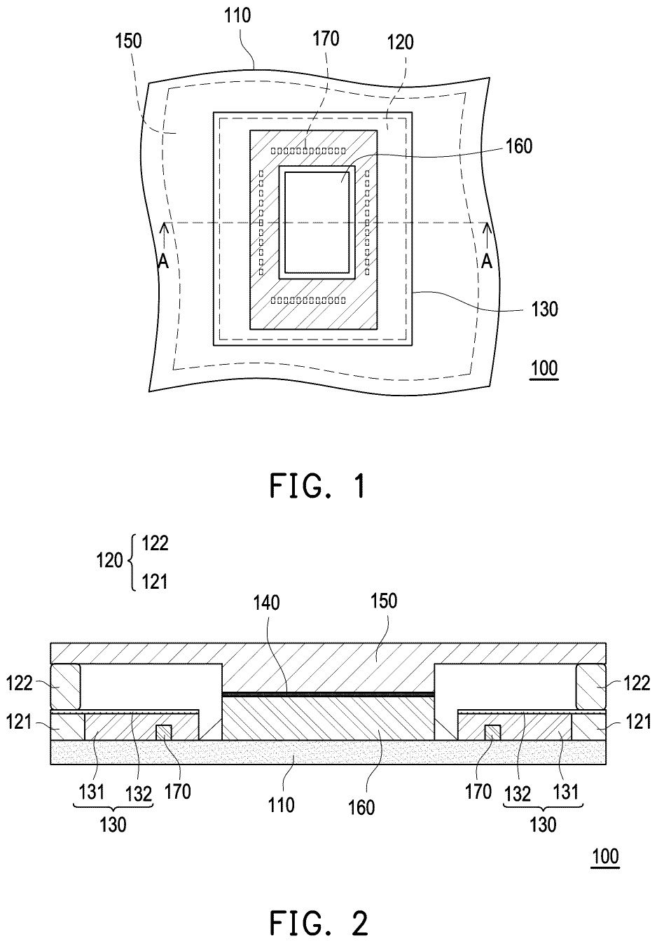

FIG. 1 is a top schematic diagram of an electronic package structure according to an embodiment of the disclosure. FIG. 2 is a partial cross-sectional diagram of the electronic package structure of FIG. 1. Referring to FIG. 1 and FIG. 2 at the same time, in this embodiment, the electronic package structure 100 includes a substrate 110, a first electronic element 160, at least one second electronic element 170, a liquid metal 140, a heat dissipating member 150, an electrically insulating cover 130, and a retaining wall 120. The first electronic element 160 and the second electronic element 170 adjacent to each other are respectively disposed on the substrate 110. The liquid metal 140 is disposed on the first electronic element 160. The heat dissipating member 150 is disposed on the first electronic element 160 and presses against the liquid metal 140 so that the heat generated by the first electronic element 160 is transferred to the heat dissipating member 150 through the liquid metal 140.

The electrically insulating cover 130 of this embodiment includes a carrier 132 and an electrically insulating glue 131. The carrier 132 is translucent and electrically insulating, and is made of, for example, transparent polyethylene terephthalate (PET) or transparent polyimide. The electrically insulating glue 131 is, for example, a UV light glue with a viscosity greater than 2000 cP (at 25° C.). It is coated on the carrier 132 and pasted on the substrate 110 along with the carrier 132, so that the electrically insulating glue 131 covers and packages the second electronic element 170. At least a portion of the pressed liquid metal 140 overflows the first electronic element 160, but is isolated from the second electronic element 170 via the electrically insulating glue 131 and the carrier 132.

Here, the first electronic element 160 may include active elements such as a central processing unit (CPU) and a graphics processing unit (GPU), while the second electronic element 170 may include passive elements such as capacitors, resistors, and inductors. In one embodiment, the number of the second electronic elements 170 may be multiple, and they are respectively disposed around the first electronic elements 160. In another embodiment, the second electronic element 170 may include a multi-layer ceramic capacitor (MLCC), but the disclosure is not limited thereto. The substrate 110 is, for example, a motherboard carrying the above-mentioned electronic elements, and is disposed with multiple circuits (not shown).

As shown in FIG. 2, the retaining wall 120 of this embodiment is composed of component one 121 and component two 122, which are jointly pressed between the heat dissipating member 150 and the substrate 110, and a portion of the carrier 132 is clamped between the component one 121 and the component two 122. The following will provide a more detailed explanation of the manufacturing process.

In this embodiment, the retaining wall 120 serves as a cushion member, which is deformably pressed between the heat dissipating member 150 and the substrate 110 to serve as a structural cushion to withstand the pressure when the heat dissipating member 150 and the substrate 110 are combined.

In another embodiment, the retaining wall 120 may be a thermal conductive member for transferring heat energy on the substrate 110 to the heat dissipating member 150.

In another embodiment, the retaining wall 120 is an electromagnetic wave absorber to block mutual interference between the electromagnetic waves of the external environment and the electromagnetic waves of the first electronic element 160.

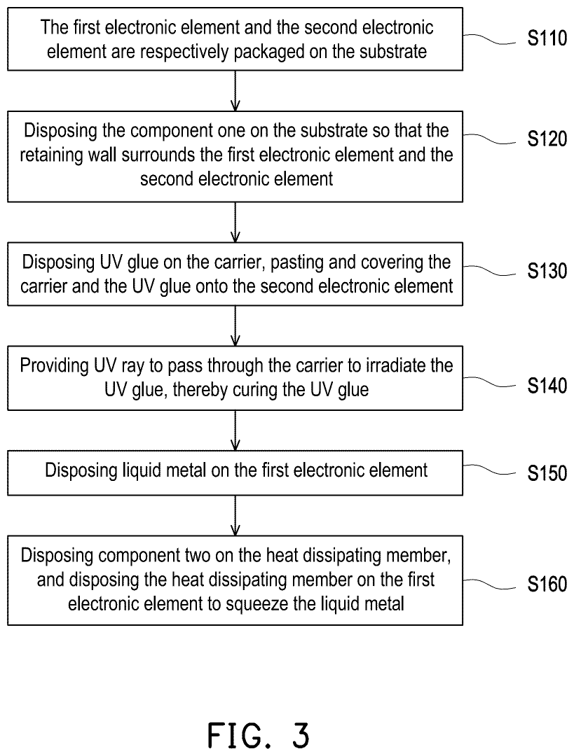

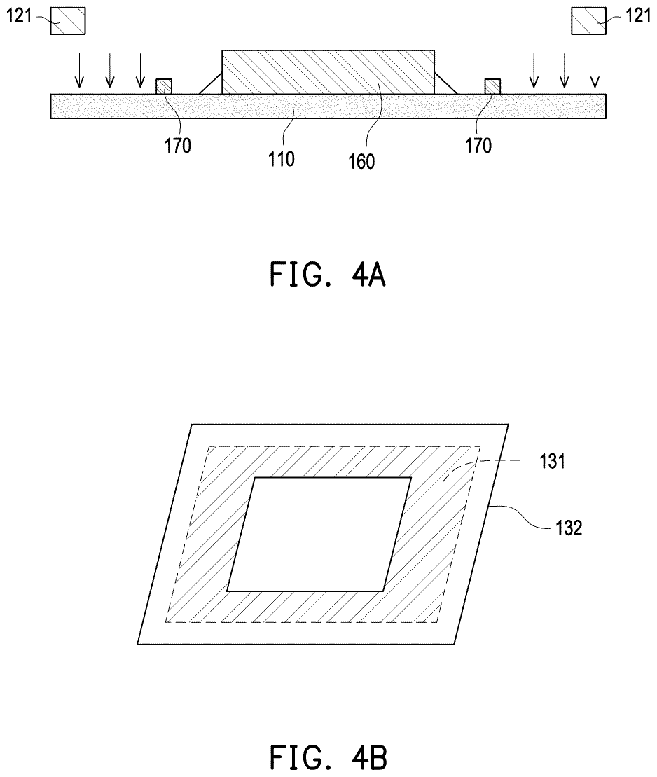

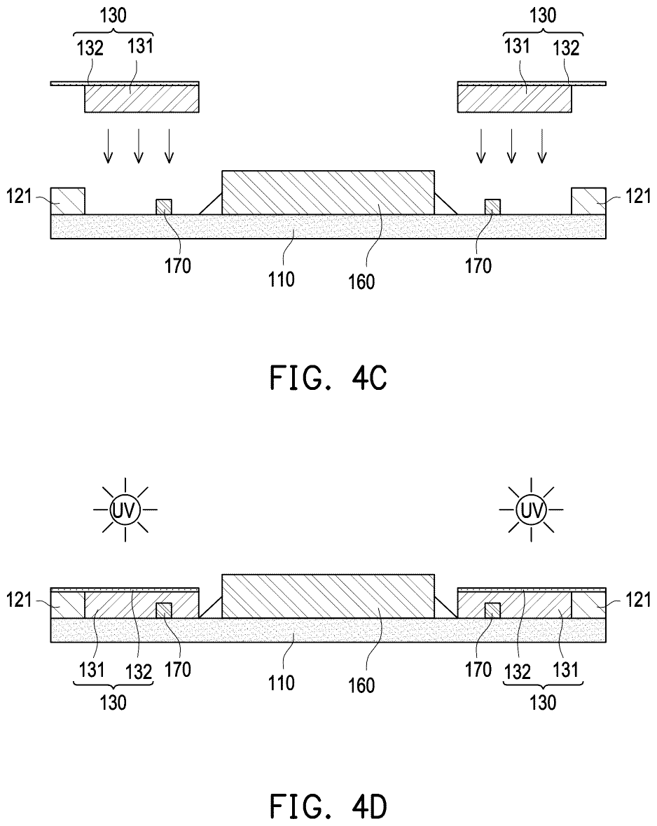

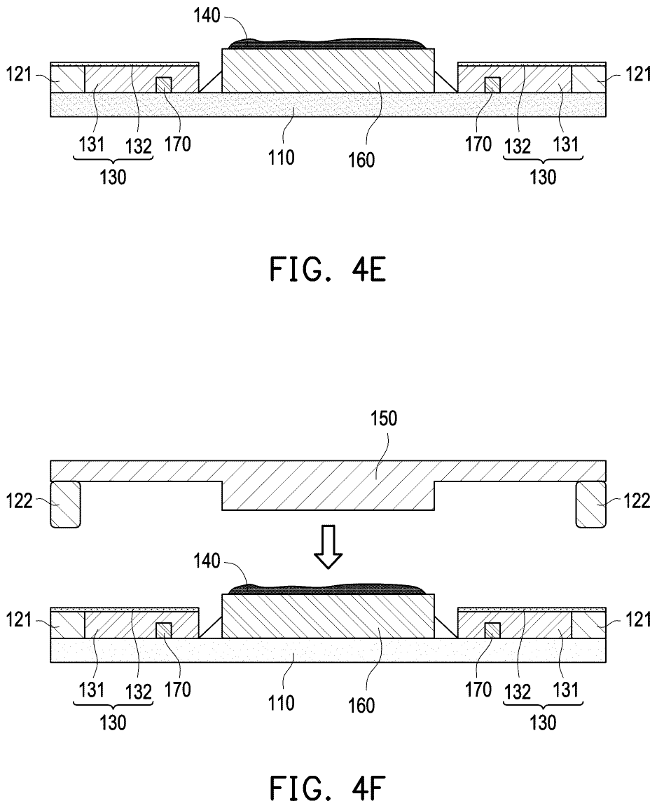

FIG. 3 is a flowchart of a manufacturing method of an electronic package structure. FIG. 4A to FIG. 4F are simple schematic diagrams of the manufacturing method of FIG. 3. Referring to FIG. 3 and correspondingly referring to FIG. 4A to FIG. 4F, the electronic package structure 100 shown in FIG. 2 is used as an example to describe the manufacturing process. In this embodiment, first in step S110, the first electronic element 160 and the second electronic element 170 are respectively packaged on the substrate 110. Next, as shown in FIG. 4A, in step S120, the component one 121 of the retaining wall 120 is disposed on the substrate 110 so that the component one 121 of the retaining wall 120 surrounds the first electronic element 160 and the second electronic element 170. Next, in step S130, as shown in FIG. 4B, the electrically insulating glue 131 is disposed on the carrier 132, and then, as shown in FIG. 4C to FIG. 4D, the carrier 132 and the electrically insulating glue 131 are pasted on the substrate 110 to cover and package the second electronic element 170. Next, in step S140, as shown in FIG. 4D, ultraviolet light UV irradiation is provided, so that the ultraviolet light UV passes through the transparent carrier 132 to irradiate and cure the electrically insulating glue 131. Next, in step S150, the liquid metal 140 is disposed on the first electronic element 160. After curing, finally in step S160, the component two 122 is disposed on the heat dissipating member 150, and the heat dissipating member 150 is disposed on the first electronic element 160 to compress (squeeze) the liquid metal 140. At this time, since the second electronic element 170 has been isolated and protected by the electrically insulating cover 130, even if the liquid metal 140 overflows out of the first electronic element 160, the overflowing liquid metal 140 is protected by the electrically insulating cover 130 and does not contact the second electronic element 170.

It should also be mentioned that in this embodiment, the heat dissipating member 150 disposed in step S160 is, for example, a copper heat dissipating plate, and a heat sink (e.g., a heat dissipating fin, a fan or related heat dissipating device, not shown here) may be additionally disposed on the other side facing away from the liquid metal 140 to facilitate transferring heat energy out of the electronic package structure 100. At the same time, in order to prevent the copper heat dissipating plate from being corroded due to direct contact with the liquid metal 140, an anti-corrosion metal layer is also disposed on the surface of the copper heat dissipating plate as an isolation layer of the copper heat dissipating plate. Furthermore, the liquid metal 140 is, for example, a low melting point alloy that is liquid at room temperature, or an alloy that is in the form of a solid sheet and becomes liquid when heated to the melting point. The composition is, for example, gallium indium tin alloy, indium bismuth tin alloy, or indium bismuth zinc alloy, etc., which have stable properties and excellent thermal conductivity (heat transfer coefficient 30-40 W/m·K) and electrical conductivity. Since it is liquid at normal temperature, it is easy to operate. That is, after at least one of the heat dissipating member 150 and the first electronic element 160 is coated with the liquid metal 140, the liquid metal 140 may be easily covered and compressed, thereby facilitating its spread within the space between the heat dissipating member 150 and the first electronic element 160. Here, the thickness of the liquid metal 140 after completion of the arrangement is 0.1 mm to 0.2 mm, thereby achieving the effect of reducing thermal resistance and quickly transferring heat energy.

Referring to FIG. 4B, FIG. 4C, FIG. 4D and FIG. 4F again, when the carrier 132 and the electrically insulating glue 131 are pasted on the substrate 110 in step S130, for the convenience of the operator to perform the pasting operation, the carrier 132 will maintain a portion at the periphery of the electrically insulating glue 131 that is not coated with the electrically insulating glue 131, thereby reducing the complexity of the pasting operation shown in FIG. 4C. That is, the operator only needs to pay attention to covering and packaging the electrically insulating glue 131 onto the second electronic element 170 without worrying about the size of the carrier 132. For example, this embodiment may provide a larger-sized carrier 132 to facilitate the operator's grip. On the premise that the second electronic element 170 is covered and packaged with the electrically insulating glue 131, the portion of the carrier 132 at the periphery of the electrically insulating glue 131 is pasted on the component one 121, and then as shown in FIG. 4F, when the heat dissipating member 150 is assembled, the aforementioned portion is clamped between the component one 121 and the component two 122 of the retaining wall 120.

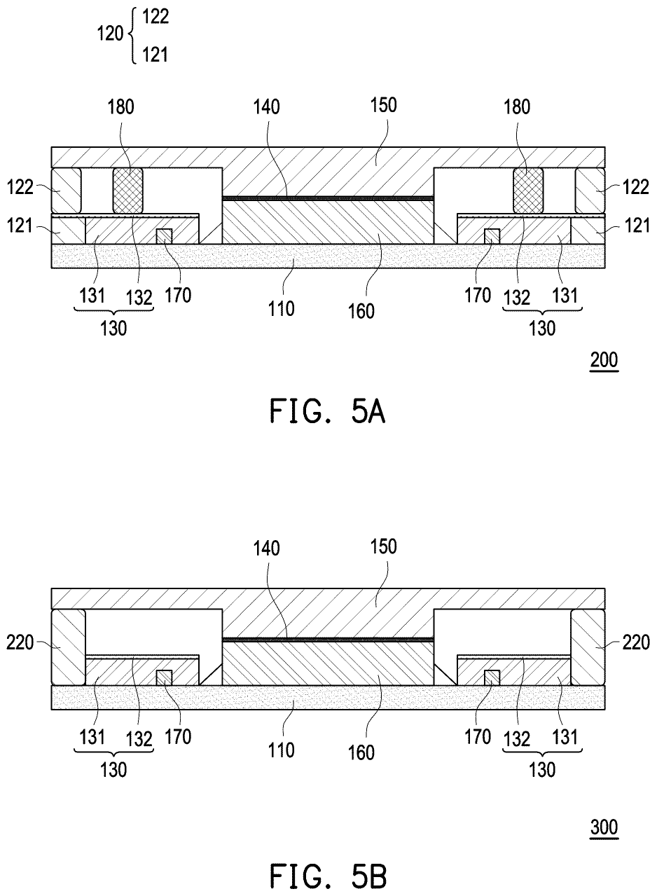

FIG. 5A and FIG. 5B respectively are schematic diagrams of electronic package structures of different embodiments of the disclosure. Referring to FIG. 5A first, in the electronic package structure 200 of this embodiment, what is different from the above is that this embodiment also includes a sponge 180, which is disposed between the heat dissipating member 150 and the carrier 132 of the electrically insulating cover 130, and is substantially located within the range of retaining wall 120. In this embodiment, the sponge 180 may be disposed on the heat dissipating member 150 first, and when the heat dissipating member 150 is disposed on the first electronic element 160 in the aforementioned step S160, the sponge 180 is also pressed between the heat dissipating member 150 and the carrier 132. Here, the sponge 180 also has cushioning properties, so it may also has sealing properties like the retaining wall 120. At the same time, when the liquid metal 140 is compressed by the heat dissipating member 150 and overflows the first electronic element 160, the sponge 180 may effectively block and absorb the liquid metal 140, thereby confining the liquid metal 140 within the space between the heat dissipating member 150, the sponge 180, the carrier 132, and the first electronic element 160. For example, when the heat dissipating member 150 is combined with the first electronic element 160, the liquid metal 140 may splash outward due to pressure, and the retaining wall 120 has not yet been completely sealed with the heat dissipating member 150 and the substrate 110, so there is still the possibility of the liquid metal 140 splashing out of the electronic package structure 100. Therefore, in this embodiment, the sponge 180 is provided as the primary barrier to block (and absorb) the splash of the liquid metal 140.

In addition, referring to the electronic package structure 300 shown in FIG. 5B. The difference from the previous embodiment is that the retaining wall 220 provided in this embodiment is a single component, which is equivalent to changing the manufacturing method shown in FIG. 4B by coating the electrically insulating glue 131 to the entire surface of the carrier 132. It should be noted that the retaining wall 220 shown in this embodiment may be disposed on the substrate 110 or alternatively may be disposed on the heat dissipating member 150. Both configurations are capable of achieving the structure shown in FIG. 5B.

To sum up, in the above-mentioned embodiments of the disclosure, the electronic package structure and its manufacturing method provide a stable heat dissipation mechanism for electronic elements and circuits through convenient and effective protection measures. During manufacturing, the electrically insulating glue is first coated on the carrier, and then the carrier and the electrically insulating glue are pasted on the substrate to cover and package the second electronic element. Next, the electrically insulating glue is cured. Finally, the liquid metal is disposed on the first electronic element, and the heat dissipating member is pressed on the first electronic element, so that the heat generated by the first electronic element is transferred to the heat dissipating member through the liquid metal.

Importantly, since the aforementioned carrier and electrically insulating glue package the second electronic element and isolate it from surrounding elements, when the heat dissipating member is disposed on the first electronic element and presses against the liquid metal, the liquid metal overflowing from the first electronic element may be isolated via the carrier and the electrically insulating glue, effectively preventing the liquid metal from contacting the second electronic element and causing short circuit.

What is claimed is:

1. An electronic package structure, comprising:
a substrate,
a first electronic element, disposed on the substrate;
at least one second electronic element, disposed on the substrate and adjacent to the first electronic element;
a liquid metal, disposed on the first electronic element;
a heat dissipating member, disposed on the first electronic element and pressed against the liquid metal, wherein heat generated by the first electronic element is transferred to the heat dissipating member through the liquid metal;
a carrier, being translucent and electrically insulating; and
an electrically insulating glue, coated on the carrier and pasted on the substrate along with the carrier, so that the electrically insulating glue covers and packages the second electronic element, wherein at least a portion of the pressed liquid metal overflows the first electronic element and is isolated from the second electronic element via the electrically insulating glue and the carrier.

2. The electronic package structure according to claim 1, further comprising a retaining wall, pressed between the heat dissipating member and the substrate.

3. The electronic package structure according to claim 2, wherein the retaining wall comprises a component one and a component two, the component one is disposed on the substrate, the component two is disposed on the heat dissipating member, and a portion of the carrier is clamped between the component one and the component two.

4. The electronic package structure according to claim 2, wherein the retaining wall is a cushion member, which is deformably pressed between the heat dissipating member and the substrate.

5. The electronic package structure according to claim 2, wherein the retaining wall is a thermal conductive member that transfers heat energy on the substrate to the heat dissipating member.

6. The electronic package structure according to claim 2, wherein the retaining wall is an electromagnetic wave absorber to block mutual interference between electromagnetic waves of an external environment and electromagnetic waves of the first electronic element.

7. The electronic package structure according to claim 1, wherein the first electronic element is a processor and the second electronic element is a capacitor.

8. The electronic package structure according to claim 1, wherein the electrically insulating glue is an ultraviolet light curable glue.

9. The electronic package structure according to claim 1, further comprising a sponge, disposed between the heat dissipating member and the carrier to block and absorb the liquid metal that is pressed by the heat dissipating member and is overflowing the first electronic element.

10. A manufacturing method of an electronic package structure, comprising:
respectively packaging a first electronic element and a second electronic element on a substrate;
disposing ultraviolet light glue on a carrier, pasting and covering the carrier and the ultraviolet light glue onto the second electronic element;
providing ultraviolet light to pass through the carrier to irradiate the ultraviolet light glue, thereby curing the ultraviolet light glue;
disposing a liquid metal on the first electronic element;
disposing a heat dissipating member on the first electronic element to compress the liquid metal.

11. The manufacturing method of the electronic package structure according to claim 10, wherein the electronic package structure further comprises a retaining wall, and the manufacturing method further comprises:
disposing the retaining wall on the substrate or the heat dissipating member, so that when the heat dissipating member is disposed on the first electronic member, the retaining wall is pressed between the heat dissipating member and the substrate.

12. The manufacturing method of the electronic package structure according to claim 11, wherein when the retaining wall is disposed on the substrate, the retaining wall surrounds the first electronic element and the second electronic element.

13. The manufacturing method of the electronic package structure according to claim 11, wherein the retaining wall comprises a component one and a component two, and the manufacturing method further comprises:
disposing the component one on the substrate; and
disposing the component two on the heat dissipating member.

14. The manufacturing method of the electronic package structure according to claim 13, further comprising:
pasting a portion of the carrier on the component one when the carrier and the ultraviolet light glue are pasted and covered on the second electronic element; and
pressing the portion of the carrier between the component one and the component two when the heat dissipating member is disposed on the first electronic element.

15. The manufacturing method of the electronic package structure according to claim 10, further comprising:
providing a sponge and pressing the sponge between the heat dissipating member and the carrier, so that the sponge blocks and absorbs the liquid metal that is pressed by the heat dissipating member and is overflowing the first electronic element.
